(19) United States
(12) Patent Application Publication
(10) Pub. No.: US 2024/0170421 A1
(43) Pub. Date: May 23, 2024

(54) SEMICONDUCTOR DEVICE

(71) Applicant: RENESAS ELECTRONICS CORPORATION, Tokyo (JP)

(72) Inventors: Teruhiro KUWAJIMA, Tokyo (JP); Tohru KAWAI, Tokyo (JP); Takashi TONEGAWA, Tokyo (JP)

(21) Appl. No.: 18/484,982

(22) Filed: Oct. 11, 2023

(30) Foreign Application Priority Data
Nov. 21, 2022 (JP) 2022-185389

(51) Int. Cl. H01L 23/00

(52) U.S. Cl. CPC H01L 24/05; H01L 24/03; H01L 24/06; H01L 2224/0345; H01L 2224/03464; H01L 2224/0391; H01L 2224/05005; H01L 2224/05011; H01L 2224/05013; H01L 2224/05022; H01L 2224/05026; H01L 2224/0508; H01L 2224/05124; H01L 2224/05138; H01L 2224/05147; H01L 2224/05155; H01L 2224/05164; H01L 2224/05166; H01L 2224/05186; H01L 2224/05553; H01L 2224/05562; H01L 2224/05571; H01L 2224/05573; H01L 2224/05644; H01L 2224/06135; H01L 2924/01014; H01L 2924/0132; H01L 2924/0133; H01L 2924/04941

(57) ABSTRACT

A pad is formed on an interlayer insulation film, a first insulation film is formed on the interlayer insulation film so as to cover the pad, and a second insulation film is formed on the first insulation film so as to cover the pad. The first insulation film includes a first opening partially exposing the pad, and the second insulation film includes a second opening partially exposing the pad, and the second opening is included in the first opening in plan view. The first insulation film is made of silicon oxide, and the second insulation film is made of silicon nitride or silicon oxynitride. A nickel plating film is formed on the pad exposed from the second opening. A distance from an outer circumference of the pad to an inner wall of the first opening increases in accordance with a thickness of the nickel plating film.

### CROSS-REFERENCE TO RELATED APPLICATION

The disclosure of Japanese Patent Application No. 2022-185389 filed on Nov. 21, 2022, including the specification, drawings and abstract is incorporated herein by reference in its entirety.

### BACKGROUND

The present invention relates to a semiconductor device, and can be used suitably for, for example, a semiconductor device having a pad.

There is disclosed technique listed below.

[Patent Document 1] Japanese Unexamined Patent Application Publication No. 2019-12738

A semiconductor device is manufactured by forming a semiconductor element such as a MISFET on a semiconductor substrate, forming a r multilayer wiring structure having a plurality of wiring layers on the semiconductor substrate, and then forming a passivation film on the upper layer of the multilayer wiring structure. The semiconductor device also has a pad for wire bonding, and the pad is exposed from an opening formed in the passivation film. Patent Document 1 describes a technique for a semiconductor device having a pad electrode.

### SUMMARY

In a semiconductor device having a pad, it is desirable to improve reliability.

Other issues and novel features will become apparent from the description herein and the accompanying drawings.

According to one embodiment, a semiconductor device includes: a semiconductor substrate; a first insulation film formed on the semiconductor substrate; a pad formed on the first insulation film; a second insulation film made of silicon oxide and formed on the first insulation film so as to cover the pad; and a third insulation film made of silicon nitride or silicon oxynitride and formed on the second insulation film. The second insulation film has a first opening partially exposing the pad, the third insulation film has a second opening partially exposing the pad, and the second opening is included in the first opening in plan view. A nickel plating film is formed on the pad exposed from the second opening. A distance from an outer circumference of the pad to an inner wall of the first opening increases in accordance with a thickness of the nickel plating film.

According to another embodiment, a semiconductor device includes: a semiconductor substrate; a first insulation film formed on the semiconductor substrate; a pad formed on the first insulation film; a second insulation film made of silicon oxide and formed on the first insulation film so as to cover the pad; a third insulation film made of silicon nitride or silicon oxynitride and formed on the second insulation film; and a fourth insulation film formed on the third insulation film. The second insulation film has a first opening partially exposing the pad, the third insulation film has a second opening partially exposing the pad, and the second opening is included in the first opening in plan view. A nickel plating film is formed on the pad exposed from the second opening. The fourth insulation film is an inorganic insulation film, and a Young's modulus of the fourth insulation film is lower than a Young's modulus of the third insulation film.

According to one embodiment, reliability of a semiconductor device can be improved.

### BRIEF DESCRIPTIONS OF THE DRAWINGS

FIG. 1 is a whole plan view of a semiconductor device according to a first embodiment.

FIG. 2 is a cross-sectional view of a principal part of the semiconductor device according to the first embodiment.

FIG. 3 is a plan view of a pad formation region.

FIG. 4 is a cross-sectional view of a principal part of the semiconductor device according to the first embodiment.

FIG. 5 is a cross-sectional view of a principal part of the semiconductor device according to the first embodiment in a manufacturing process.

FIG. 6 is a cross-sectional view of a principal part of the semiconductor device in the manufacturing process, continued from FIG. 5.

FIG. 7 is a cross-sectional view of a principal part of the semiconductor device in the manufacturing process, continued from FIG. 6.

FIG. 8 is a cross-sectional view of a principal part of the semiconductor device in the manufacturing process, continued from FIG. 7.

FIG. 9 is a cross-sectional view of a principal part of the semiconductor device in the manufacturing process, continued from FIG. 8.

FIG. 10 is a cross-sectional view of a principal part of the semiconductor device in the manufacturing process, continued from FIG. 9.

FIG. 11 is a cross-sectional view of a principal part of the semiconductor device in the manufacturing process, continued from FIG. 10.

FIG. 12 is a cross-sectional view of a principal part of a semiconductor device according to a study example.

FIG. 13 is a plan view of a pad formation region according to the study example.

FIG. 14 is a graph showing correlation between a thickness T1 of a nickel plating film and a distance L1 required to prevent cracks from forming in the insulation film.

FIG. 15 is a cross-sectional view of a principal part of a semiconductor device according to a second embodiment.

FIG. 16 is a plan view of a pad formation region according to the second embodiment.

FIG. 17 is a cross-sectional view of a principal part of the semiconductor device according to the second embodiment in a manufacturing process.

FIG. 18 is a cross-sectional view of a principal part of the semiconductor device in the manufacturing process, continued from FIG. 17.

FIG. 19 is a cross-sectional view of a principal part of a semiconductor device according to a third embodiment.

FIG. 20 is a cross-sectional view of a principal part of a semiconductor device according to a fourth embodiment.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Embodiments will be explained in detail below with reference to the drawings. Note that components having the same function are denoted by the same reference symbols throughout all the drawings for describing the embodiments, and the repetitive description thereof is omitted. In addition, in the following embodiments, the description of the same or similar portions is not repeated in principle unless otherwise particularly required.

Also, in some drawings used in the embodiments, hatching may be omitted even in a cross-sectional view so as to make the drawings easy to see. And, hatching may be used even in a plan view so as to make the drawings easy to see.

### First Embodiment

### Whole Structure of Semiconductor Device

A semiconductor device according to the first embodiment will be described with reference to the drawings.

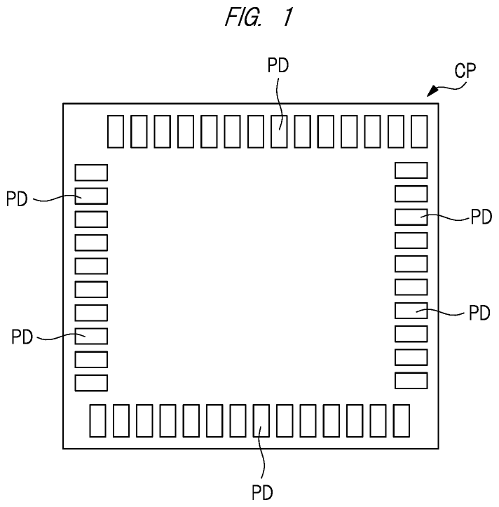

FIG. 1 is a whole plan view of a semiconductor device (semiconductor chip) CP according to the present embodiment, and shows a whole plan view of an upper side of the semiconductor device (semiconductor chip) CP.

The semiconductor device (semiconductor chip) CP according to the present embodiment has an upper surface which is one main surface, and a back surface (lower surface) which is a main surface on the side opposite to the upper surface, and FIG. 1 shows the upper surface of the semiconductor device CP. In the semiconductor device CP, a pad PD is formed on the upper surface of the semiconductor device CP, and the main surface on the side opposite to the main surface (that is, the upper surface) on which the pad PD is formed is herein called the back surface of the semiconductor device CP.

The semiconductor device CP has a plurality of pads (pad electrode, electrode pad, bonding pad) PD on its upper surface as shown in FIG. 1. The pad PD serves as a terminal for external connections of the semiconductor device CP. The pad PD is a pad for wire bonding. Although described in detail later, a metal film (plating film) ME is formed on each pad PD. When the upper surface of the semiconductor device CP is viewed from above, the metal film ME is observed, but the pad PD is hidden under the metal film ME. When a semiconductor package or the like is manufactured using the semiconductor device CP, a wire is bonded to the metal film ME on the pad PD, and the wire and the pad PD are electrically connected to each other through the metal film ME.

The planar shape of the semiconductor device CP is a quadrangle, and more specifically, a rectangle, but corners of the rectangle may be rounded. In the case of FIG. 1, on the upper surface of the semiconductor device CP, a plurality of stacked bodies each of which is a stack of the pad PD and the metal film ME formed on the pad PD are arranged in a line along the outer circumference of the upper surface of the semiconductor device CP. In the case of FIG. 1, the plurality of stacked bodies each of which is the stack of the pad PD and the metal film ME formed on the pad PD are arranged (arrayed) along the four sides on the upper surface of the semiconductor device CP. However, the arrangement is not limited to this, and they may be arranged (arrayed) along three sides, two sides, or one side. Also, in the case of FIG. 1, the stacked bodies each of which is the stack of the pad PD and the metal film ME formed on the pad PD are arranged in one row. However, the arrangement is not limited to this, and they may be arranged in a plurality of rows (for example, two rows), or may be arranged in a so-called lattice arrangement. Also, the number of stacked bodies each of which is the stack of the pad PD and the metal film ME formed on the pad PD, included in the semiconductor device CP can be changed as necessary.

### Internal Structure of Semiconductor Device

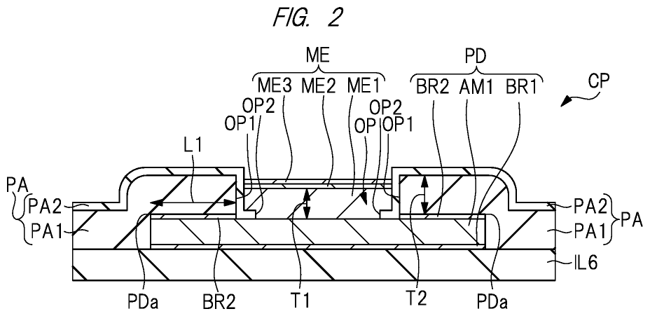

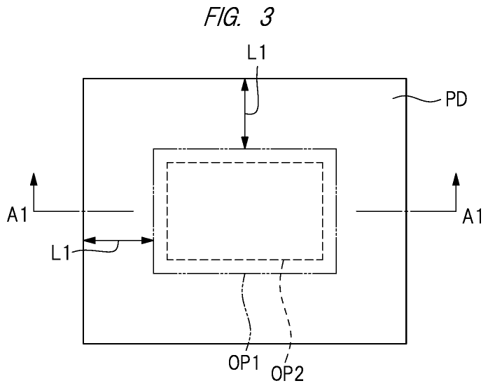

FIG. 2 is a cross-sectional view of a principal part of the semiconductor device (semiconductor chip) CP according to the present embodiment, and shows a cross section across the pad PD. In FIG. 2, illustration of a structure below an interlayer insulation film IL6 is omitted. FIG. 3 is a plan view showing a pad formation region. For simplicity of understanding, the pad PD is illustrated with a solid line, a position of an opening OP1 is illustrated with a double-dotted line, and a position of opening OP2 is illustrated with a dotted line. A cross-sectional view at a position of a line A1-A1 in FIG. 3 roughly corresponds to FIG. 2.

As shown in FIG. 2, the pad PD is formed on the interlayer insulation film IL6, and an insulation film PA is formed on the interlayer insulation film IL6 to cover a portion of the pad PD. The insulation film PA is made of an insulation film PA1 and an insulation film PA2 on the insulation film PA1. The insulation film PA1 is made of silicon oxide, and the insulation film PA2 is made of silicon nitride or silicon oxynitride. Therefore, the insulation film PA1 is a silicon oxide film, and the insulation film PA2 is a silicon nitride film or a silicon oxynitride film (SiON film). The upper surface of the insulation film PA1 is in contact with the insulation film PA2. The insulation film PA can also be regarded as a stacked film (stacked insulation film) where a plurality of the insulation films (specifically, the two insulation films of the insulation film PA1 and insulation film PA2) are staked. The thickness of the insulation film PA1 can preferably be about 0.2 to 5.0 μm. The thickness of the insulation film PA2 can preferably be about 0.1 to 2.0 μm.

A portion of the pad PD is exposed from an opening OP of the insulation film PA. However, the other portion of the pad PD is covered with the insulation film PA. That is, the pad PD is exposed from the opening OP of the insulation film PA, but a portion of the pad PD not overlapping the opening OP in plan view is covered with the insulation film PA. Specifically, the center of the pad PD is not covered with the insulation film PA, and the outer circumference of the pad PD is covered with the insulation film PA.

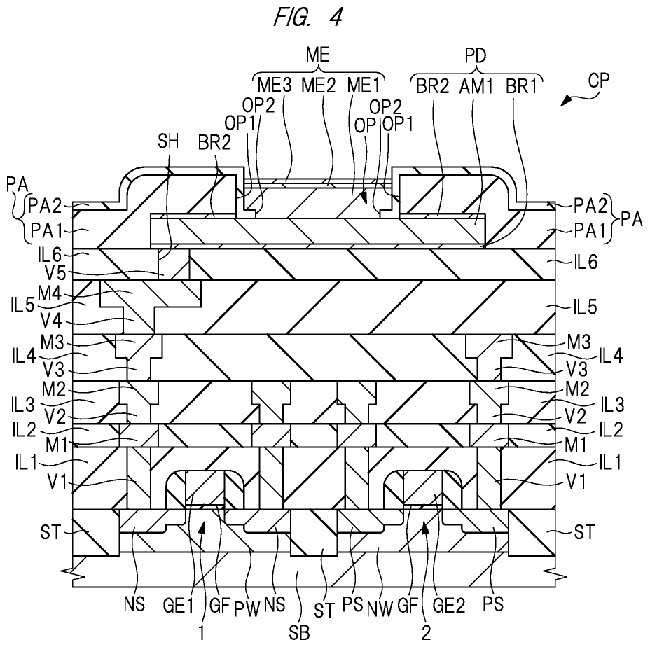

A case in description of a plan view of a component of the semiconductor device CP corresponds to a case of view in a plane substantially parallel to a main surface of a semiconductor substrate SB (see FIG. 4 described later) configuring the semiconductor device CP.

The insulation film PA has the opening OP exposing a portion of the pad PD. Since the insulation film PA is the stacked film of the insulation film PA1 and insulation film PA2, the opening OP of the insulation film PA is made of the opening OP2 of the insulation film PA2 and the opening OP1 of the insulation film PA1. Note that the opening OP2 penetrates through the insulation film PA2, and the opening OP1 penetrates through the insulation film PA1. The opening OP2 of the insulation film PA2 and the opening OP1 of the insulation film PA1 have the following relationship.

That is, as can be seen from FIG. 2 and FIG. 3, the plane dimension (plane area) of the opening OP2 of the insulation film PA2 is smaller than the plane dimension (plane area) of the opening OP1 of the insulation film PA1, and the opening OP2 of the insulation film PA2 is included in the opening OP1 of the insulation film PA1 in plan view. That is, in plan view, the opening OP2 of the insulation film PA2 overlaps the opening OP1 of the insulation film PA1, and the inner wall of the opening OP2 of the insulation film PA2 is inside the inner wall of the opening OP1 of the insulation film PA1. The plane dimension (plane area) of the opening OP1 of the insulation film PA1 is smaller than the plane dimension (plane area) of the pad PD, and the opening OP1 of the insulation film PA1 is included in the pad PD in plan view.

Since the opening OP2 of the insulation film PA2 is included in the opening OP1 of the insulation film PAL in plan view, the inner wall (side wall) of the opening OP1 of the insulation film PA1 is covered with the insulation film PA2. As a result, the insulation film PA1 made of silicon oxide is covered with the insulation film PA2 made of silicon nitride or silicon oxynitride even in the inner wall of the opening OP1 of the insulation film PA1, and therefore, moisture absorption of the insulation film PA1 can be prevented more accurately. That is, because the silicon oxide film tends to absorb the moisture, and therefore, there is concern that the insulation film PA1 absorbs the moisture from the inner wall of the opening OP1 of the insulation film PA1 if the inner wall of the opening OP1 of the insulation film PA1 made of silicon oxide is not covered with the insulation film PA2 made of silicon nitride or silicon oxynitride as different from the first embodiment. In contrast, in the present embodiment, the inner wall of the opening OP1 of the insulation film PA1 made of silicon oxide is covered with the insulation film PA2 made of silicon nitride or silicon oxynitride, and therefore, the moisture can be prevented from being absorbed by the insulation film PA1 from the inner wall of the opening OP1 of the insulation film PA1, and therefore, the moisture absorption of the insulation film PA1 can be prevented more accurately.

At the inner wall of the opening OP1 of the insulation film PA1, an end surface of a barrier film BR2 that configures the pad PD is exposed. However, since the inner wall of the opening OP1 of the insulation film PA is covered with the insulation film PA2, the end surface of the barrier conductor film BR2 exposed at the inner wall of the opening OP1 of the insulation film PA1 is also covered with the insulation film PA2. If the inner wall of the opening OP1 of the insulation film PA1 is not covered with the insulation film PA2 as different from the first embodiment, there is a risk of oxidation of the end surface of the barrier conductor film BR2 exposed at the inner wall of the opening OP1 of the insulation film PA1 during a period to a plating process to form the metal film ME. In contrast, in the first embodiment, since the inner wall of the opening OP1 of the insulation film PA1 is covered with the insulation film PA2, the end surface of the barrier conductor film BR2 exposed at the inner wall of the opening OP1 of the insulation film PA1 is also covered with the insulation film PA2. Therefore, the end surface of the barrier conductor film BR2 exposed at the inner wall of the opening OP1 of the insulation film PA1 can be prevented from being oxidized during the period to the plating process to form the metal film ME.

In the present embodiment, since the inner wall of the opening OP1 of the insulation film PA1 is covered with the insulation film PA2, the inner wall of the opening OP of the insulation film PA is made of the inner wall of the opening OP2 of the insulation film PA2 (that is, the end surface of the insulation film PA2) and the surface of the insulation film PA2 located on the inner wall of the opening OP1 of the insulation film PA1. Accordingly, the inner wall of the opening OP of the insulation film PA is made of the insulation film PA2. The portion of the pad PD exposed from the opening OP of the insulation film PA corresponds to a portion of the pad PD exposed from the opening OP2 of the insulation film PA2. The position and shape (area) of the opening OP of the insulation film PA is substantially defined by the opening OP2 of the insulation film PA2, and the exposed area of the pad PD (that is an area of the portion of the pad PD exposed from the opening OP of the insulation film PA1) is defined by the opening OP2 of the insulation film PA2.

The insulation film PA is the top layer of the semiconductor device CP, and can function as a surface protective film. That is, the insulation film PA is a passivation film. Each planar shape of the pad PD and the opening OP is, for example, quadrangular (more specifically, rectangular). As another form, a resin film RS described later can be further provided on the insulation film PA. However, even when the resin film RS is formed, a portion of the pad PD remains exposed from the opening OP of the insulation film PA (more specifically, the opening OP2 of the insulation film PA2).

The pad PD is an aluminum pad mainly made of aluminum (A1). Specifically, the pad PD is made of a stacked film of a barrier conductor film BR1, an A1-containing conductive film AM1 on the barrier conductor film BR1, and the barrier conductor film BR2 on the A1-containing conductive film AM1. In a portion of the pad PD located under the insulation film PA1 (that is, a portion of the same covered with the insulation film PA1), the barrier conductor film BR2 is formed on the A1-containing conductive film AM1. On the other hand, in a portion of the pad PD exposed from the opening OP1 of the insulation film PA1 (that is, a portion of the same not covered with the insulation film PA1), no barrier conductor film BR2 is formed on the A1-containing conductive film AM1. This is for removing the barrier conductor film BR2 at the portion exposed from the opening OP1 in the insulation film PA1 when the opening OP1 is formed in the insulation film PA1.

The A1-containing conductive film AM1 is preferably made of a conductive material film mainly made of aluminum (A1) (but a conductive material film that exhibits metallic conduction). As the A1-containing conductive film AM1, an aluminum film (pure aluminum film) can be used. However, the film is not limited to this, and a chemical compound film or an alloy film mainly made of aluminum (A1) can also be used. For example, a chemical compound film or an alloy film of A1 (aluminum) and Si (silicon), a chemical compound film or an alloy film of A1 (aluminum) and Cu (copper), or a chemical compound film or an alloy film of A1 (aluminum), Si (silicon) and Cu (copper) can be preferably used as the A1-containing conductive film AM1. A composition ratio (content rate) of A1 (aluminum) in the A1-containing conductive film AM1 is greater than 50 atomic %, but is more preferably equal to or greater than 98 atomic %.

The barrier conductor film BR1 and the barrier conductor film BR2 are both conductive films (preferably, conductive films that exhibit metallic conduction). The barrier conductor film BR1 of these films has a function of improving adhesion to a base member (such as the interlayer insulation film IL6) to prevent peeling. Therefore, it is desirable that the barrier conductor film BR1 has excellent adhesion to the base member (such as the interlayer insulation film IL6) and adhesion to the A1-containing conductive film AM1 formed on the barrier conductor film BR1. The barrier conductor film BR2 has a function of improving adhesion to the insulation film PA1 to prevent peeling. Therefore, it is desirable that the barrier conductor film BR2 has excellent adhesion to the A1-containing conductive film AM1 that is a base member and adhesion to the insulation film PA1 formed on the barrier conductor film BR2.

As the barrier conductor film BR1, for example, a single titanium (Ti) film, a s single titanium nitride (TiN) film, a stacked film of a titanium (Ti) film and a titanium nitride (TiN) film, a stacked film of a titanium (Ti) film, a titanium nitride (TiN) film, and a titanium (Ti) film or others can be used, and the same goes for the barrier conductor film BR2.

The A1-containing conductive film AM1 can function as the main conductor film of the pad PD. The thickness of the A1-containing conductive film AM1 is greater than the respective thicknesses of the barrier conductor films BR1 and BR2. The pad PD is mainly made of the A1-containing conductive film AM1, and therefore, can be regarded as an aluminum pad. Preferably, the thickness of the A1-containing conductive film AM1 can be about 1.3 to 2.3 μm. Preferably, the thickness of the barrier conductor film BR1 can be about 0.05 to 0.5 μm. Preferably, the thickness of the barrier conductor film BR2 can be about 0.025 to 0.2 μm.

The metal film ME including a nickel plating film (Ni plating film) ME1 is formed on the pad PD exposed from the opening OP of the insulation film PA (more specifically, the opening OP2 of the insulation film PA2). The metal film ME is a plating film formed by a plating method (preferably, electroless plating method). The metal film ME includes the nickel plating film ME1 in contact with the pad PD. Preferably, the metal film ME is made of a stacked film of the nickel plating film ME1, a palladium plating film (Pd plating film) ME2 on the nickel plating film ME1, and a gold plating film (Au plating film) ME3 on the palladium plating film ME2.

The nickel plating film MEL is in contact with the pad PD exposed from the opening OP of the insulation film PA (more specifically, the opening OP2 of the insulation film PA2). Since the barrier conductor film BR2 on the A1-containing conductive film AM1 has been already removed on the portion of the pad PD exposed from the opening OP1 of the insulation film PA1, the nickel plating film ME1 is formed on the A1-containing conductive film AM1 of the pad PD at the bottom of the opening OP of the insulation film PA (the opening OP1 of the insulation film PA1) to be in contact with the A1-containing conductive film AM1. The nickel plating film MEL is also in contact with the surface and end surface of the insulation film PA2 that configures the inner wall of the opening OP of the insulation film PA.

The palladium plating film ME2 is in contact with the upper surface of the nickel plating film ME1. The gold plating film ME3 is in contact with the upper surface of the palladium plating film ME2. The nickel plating film MEL is the lower layer of the metal film ME, the gold plating film ME3 is the upper layer of the metal film ME, and the palladium plating film ME2 is a film interposed between the nickel plating film ME1 and the gold plating film ME3.

The metal film ME is formed by a plating method (preferably, electroless plating method). That is, each of the nickel plating film ME1, the palladium plating film ME2, and the gold plating film ME3, which configure the metal film ME, is formed by a plating method (preferably, electroless plating method).

The metal film ME is not a bump electrode but a base film for wire bonding and can function as an OPM (Over Pad Metal) film. Therefore, when a semiconductor package is manufactured using the semiconductor device CP, a wire (bonding wire) functioning as a connecting member is bonded to the metal film ME, and the wire is electrically connected to the pad PD through the metal film ME.

The metal film ME is selectively formed on the pad PD exposed from the opening OP of the insulation film PA (more specifically, the opening OP2 of the insulation film PA2), and no metal film ME is formed on that portion of the pad PD covered with the insulation film PA. The metal film ME is in contact with the inner wall of the opening OP of the insulation film PA.

The thickness T1 of the nickel plating film ME1 is greater than the respective thicknesses of the palladium plating film ME2 and the gold plating film ME3, and the metal film ME functioning as the OPM film is mainly made of the nickel plating film ME1. The nickel plating film MEL receives the force (impact) applied to the metal film ME in the wire bonding process, and therefore, the stress applied to the pad PD in the wire bonding process is relieved. Therefore, the nickel plating film MEL is preferably thick to some extent. The thicker the nickel plating film MEL is, the easier the reception of the force (impact) applied to the metal film ME in the wire bonding process by the nickel plating film ME1 is. This can suppress or prevent occurrence of a crack in the metal film ME due to impacts in the wire bonding, and can also suppress or prevent impacts in the wire bonding from adversely affecting the pad PD and a structure (such as an interlayer insulation film and wiring) below the pad PD. Therefore, it is preferable that the thickness T1 of the nickel plating film ME1 is equal to or greater than 2.5 μm, more preferably equal to or greater than 3 μm or more.

The gold plating film ME3 has a function of preventing oxidation of the nickel plating film ME1. The gold plating film ME3 also has a function of making it easier to connect wires to the metal film ME in the wire bonding process when the semiconductor package is manufactured using the semiconductor device CP. The palladium plating film ME2 functions as a barrier film to prevent the diffusion of nickel in the nickel plating film ME1. It is more preferable that the metal film ME also includes the palladium plating film ME2, but it may not include it. In this case, the gold plating film ME3 is formed on the nickel plating film ME1 to be in contact with the nickel plating film ME1. The thickness of the palladium plating film ME2 can preferably be about 0.05 to 0.25 μm. The thickness of the gold plating film ME3 can preferably be about 0.05 to 0.15 μm.

Next, the cross-sectional structure of the semiconductor device CP including the structure below the interlayer insulation film IL6 will be described with reference to FIG. 4. FIG. 4 is a cross-sectional view of a principal part of the semiconductor device CP according to the present embodiment, and shows the cross section of the semiconductor device including the structure below the interlayer insulation film IL6 shown in FIG. 2.

In the semiconductor device CP according to the present embodiment, a semiconductor element such as a MISFET is formed on a main surface of the semiconductor substrate SB, and a multilayer wiring structure including a plurality of wiring layers is formed on the semiconductor substrate SB. A configuration example of the semiconductor device according to the present embodiment will be specifically described below.

As shown in FIG. 4, the semiconductor element such as the MISFET (Metal Insulator Semiconductor Field Effect Transistor) is formed on the semiconductor substrate SB made of single crystal silicon or the like. A plurality of MISFETs are formed on the semiconductor substrate SB. However, FIG. 4 typically shows two MISFETs (here, an n-channel type MISFET 1 and a p-channel type MISFET 2) of the MISFETs.

On the main surface of the semiconductor substrate SB, an element isolation region ST is formed by a STI (Shallow Trench Isolation) method or the like, and the MISFET 1 and MISFET 2 are formed in an active region defined by the element isolation region ST in the semiconductor substrate SB. The element isolation region ST is made of an insulation film embedded in a trench formed in the semiconductor substrate SB.

A p-type well PW and an n-type well NW are formed in the semiconductor substrate SB, a gate electrode GE1 for the n-channel MISFET 1 is formed on the p-type well PW through a gate insulation film GF, and a gate electrode GE2 for the p-channel MISFET 2 is formed on the n-type well NW through the gate insulation film GF. The gate insulation film GF is made of, for example, a silicon oxide film, and each of the gate electrodes GE1 and GE2 is made of, for example, a polycrystalline silicon film doped with an impurity.

An n-type semiconductor region NS for source/drain of the n-channel MISFET 1 is formed in the p-type well PW of the semiconductor substrate SB, and a p-type semiconductor region PS for source/drain of the p-channel MISFET 2 is formed in the n-type well NW of the semiconductor substrate SB. The n-channel MISFET 1 is made of the gate electrode GE1, the gate insulation film GF under the gate electrode GE1, and the n-type semiconductor regions NS (source/drain regions) formed in the semiconductor substrate SB so that they are located on both sides of the gate electrode GE1. The p-channel MISFET 2 is made of the gate electrode GE2, the gate insulation film GF under the gate electrode GE2, and the p-type semiconductor regions PS (source/drain regions) formed in the semiconductor substrate SB so that they are located on both sides of the gate electrode GE2. The n-type semiconductor region NS and the p-type semiconductor region PS can also have a LDD (Lightly Doped Drain) structure. In this case, a sidewall insulation film also called a sidewall spacer is formed on the sidewalls of the gate electrodes GE1 and GE2. A metal silicide layer (not illustrated) may be formed on each of the n-type semiconductor region NS, the p-type semiconductor region PS, the gate electrode GE1, and the gate electrode GE2 by using a salicide (Seif-Aligned Silicide) technique.

The MISFET is described here as the example of the semiconductor element to be formed in the semiconductor substrate SB. However, not this but a capacitive element, a resistive element, a memory element, a transistor with a different configuration or the like may also be formed.

Also, the single-crystal silicon substrate is described here as the example of the semiconductor substrate SB. However, an SOI (Silicon On Insulator) substrate or the like can be also used as another form of the semiconductor substrate SB.

On the semiconductor substrate SB, a multilayer wiring structure made of a plurality of interlayer insulation films and a plurality of wiring layers is formed.

That is, a plurality of interlayer insulation films IL1, IL2, IL3, IL4, and IL5 are formed on the semiconductor substrate SB. And, a plug V1, via portions V2, V3, and V4, and wirings M1, M2, M3, and M4 are formed in the plurality of interlayer insulation films IL1, IL2, IL3, IL4, and IL5. Also, the interlayer insulation film IL6 is formed on the interlayer insulation film IL5, and the pad PD is formed on the interlayer insulation film IL6. A wiring (not illustrated) in the same layer as that of the pad PD can also be formed on the interlayer insulation film IL6.

Specifically, the interlayer insulation film IL1 is formed on the semiconductor substrate SB to cover the MISFET 1 and MISFET 2, the plug V1 is embedded in the interlayer insulation film IL1, the interlayer insulation film IL2 is formed on the interlayer insulation film IL1, and the wiring M1 is embedded in the interlayer insulation IL2. Then, the interlayer insulation film IL3 is formed on the interlayer insulation film IL2, the wiring M2 is embedded in the interlayer insulation film IL3, the interlayer insulation film IL4 is formed on the interlayer insulation film IL3, and the wiring M3 is embedded in the interlayer insulation film IL4. Then, the interlayer insulation film IL5 is formed on the interlayer insulation film IL4, the wiring M4 is embedded in the interlayer insulation film IL5, the interlayer insulation film IL6 is formed on the interlayer insulation film IL5, and the pad PD is formed on the interlayer insulation film IL6. Each of the interlayer insulation films IL1 to IL6 can be a single-layer insulation film (for example, silicon oxide film) or a stacked film of a plurality of insulation films. Then, the insulation film PA is formed on the interlayer insulation film IL6 to cover the pad PD, and the opening OP that exposes a portion of the pad PD is formed in the insulation film PA. Then, as explained with reference to FIG. 2 and shown in FIG. 4 as well, the metal film ME is formed as the OPM film on the pad PD exposed from the opening OP of the insulation film PA (more specifically, the opening OP2 of the insulation film PA2).

The plug V1 is made of a conductor and is arranged under the wiring M1. The plug V1 electrically connects the wiring M1 to various semiconductor regions, gate electrodes GE1 and GE2 and so on formed in the semiconductor substrate SB.

The via portion V2 is made of a conductor, is formed to be unified with the wiring M2, and is arranged between the wiring M2 and the wiring M1 to electrically connect the wiring M2 and the wiring M1. That is, the wiring M2 and the via portion V2 formed to be unified with the wiring M2 are embedded in the interlayer insulation film IL3 by using a dual-damascene method. As another form, it is possible to separately form the via portion V2 and the wiring M2 by using a single-damascene method, and this also goes for the via portions V3, V4, and V5.

The via portion V3 is made of a conductor, is formed to be unified with the wiring M3, and is arranged between the wiring M3 and the wiring M2 to electrically connect the wiring M3 and the wiring M2. That is, the wiring M3 and the via portion V3 formed to be unified with the wiring M3 are embedded in the interlayer insulation film IL4 by using the dual-damascene method. The via portion V4 is made of a conductor, is formed to be unified with the wiring M4, and is arranged between the wiring M4 and the wiring M3 to electrically connect the wiring M4 and the wiring M3. That is, the wiring M4 and the via portion V4 formed to be unified with the wiring M4 are embedded in the interlayer insulation film IL5 by using the dual-damascene method. Here, the wirings M1, M2, M3, and M4 are illustrated and described as damascene wirings (embedded wirings) formed by the damascene method. However, the wirings are not limited to the damascene wirings, and they can be formed by patterning a conductive film for wiring, so they can be, for example, aluminum wiring.

In the interlayer insulation film IL6, an opening (through hole) SH is formed at a position overlapping the pad PD in plan view, and the via portion V5 is formed (embedded) in the opening SH. The via portion V5 is made of a conductor and is arranged between the pad PD and the wiring M4 to electrically connect the pad PD and the wiring M4. That is, the via portion V5 is embedded in the interlayer insulation film IL6 by using the single damascene method.

In the present embodiment, the via portion V5 and the pad PD are formed separately. However, as another form, the via portion V5 can be formed to be unified with the pad PD. When the via portion V5 is formed to be unified with the pad PD, part of the pad PD is embedded in the opening SH of the interlayer insulation film IL6 to form the via portion V5. Note that FIG. 4 shows the cross section crossing the via portion V5, and therefore, also shows the via portion V5. However, in FIG. 2, illustration of the via portion V5 is omitted.

The configurations of the pad PD, insulation film PA (including the opening OP), and metal film ME are as explained with reference to FIG. 2, and therefore, the repetitive description thereof is omitted here.

### Manufacturing Process of Semiconductor Device

The manufacturing process of the semiconductor device CP according to the present embodiment will be described with reference to FIG. 5 to FIG. 11. Each of FIG. 5 to FIG. 11 is a cross-sectional view of a principal part of the semiconductor device CP according to the present embodiment in the manufacturing process.

The fourth wiring layer (the wiring layer including the wiring M4) shown in FIG. 4 and a structure below the fourth wiring layer be formed by using a publicly-known semiconductor manufacturing technique.

That is, as shown in FIG. 5, the element isolation region ST is formed on the semiconductor substrate SB by using the STI method, the p-type well PW and the n-type well NW are formed by using the ion implantation method, the gate electrodes GE1 and GE2 are formed on the p-type well PW and the n-type well NW through the gate insulation films GF, and the n-type semiconductor region NS and p-type semiconductor region PS are formed by using the ion implantation method. As a result, the n-channel MISFET 1 and the p-channel MISFET 2 are formed on the semiconductor substrate SB.

Then, the interlayer insulation film IL1 is formed on the semiconductor substrate SB so as to cover the MISFET 1 and MISFET 2, a contact hole is formed in the interlayer insulation film IL1 by using a photolithography technique and a dry etching technique, and the plug V1 is formed by embedding a conductive film into the contact hole.

Then, the interlayer insulation film IL2 is formed on the interlayer insulation film IL1, and then, the wiring M1 is embedded into the interlayer insulation film IL2 by using the single-damascene technique. Then, the interlayer insulation film IL3 is formed on the interlayer insulation film IL2, and then, the wiring M2 and the via portion V2 are embedded into the interlayer insulation film IL3 by using the dual-damascene technique. Then, the interlayer insulation film IL4 is formed on the interlayer insulation film IL3, and then, the wiring M3 and the via portion V3 are embedded into the interlayer insulation film IL4 by using dual-damascene technique. Then, the interlayer insulation film IL5 is formed on the interlayer insulation film IL4, and then, the wiring M4 and the via portion V4 are embedded into the interlayer insulation film IL5 by using the dual-damascene technique.

The interlayer insulation film IL5 and the wiring M4 and via portion V4 that are embedded into the interlayer insulation film IL5 are formed by using the dual-damascene technique, and then, the interlayer r insulation film IL6 is formed on the interlayer insulation film IL5.

Next, the opening SH is formed in the interlayer insulation film IL6 by using a photolithography technique and an etching technique. By the formation of the opening SH in the interlayer insulation film IL6, the upper surface of the wiring M4 is exposed at the bottom of the opening SH.

Next, a conductive film for the via portion V5 is formed on the interlayer insulation film IL6 so as to be embedded into the opening SH, and then, the conductive film (the conductive film for the via portion V5) outside the opening SH is removed while the conductive film (the conductive film for the via portion V5) in the opening SH is left by using a CMP (Chemical Mechanical Polishing) method or an etch-back method. In this manner, the via portion V5 made of the conductive film (the conductive film for the via portion V5) embedded in the opening SH can be formed.

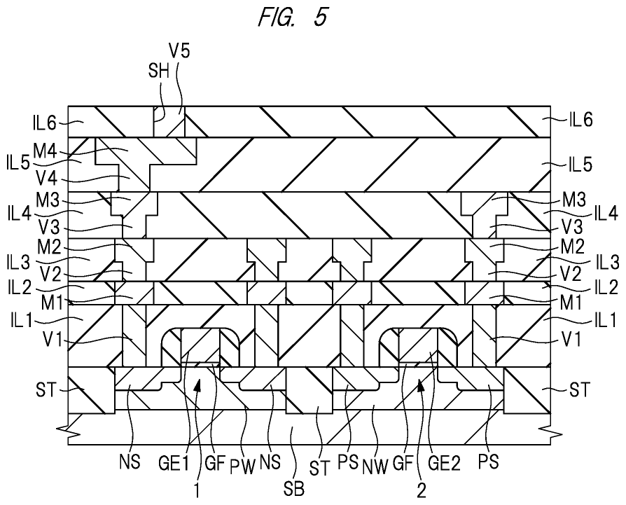

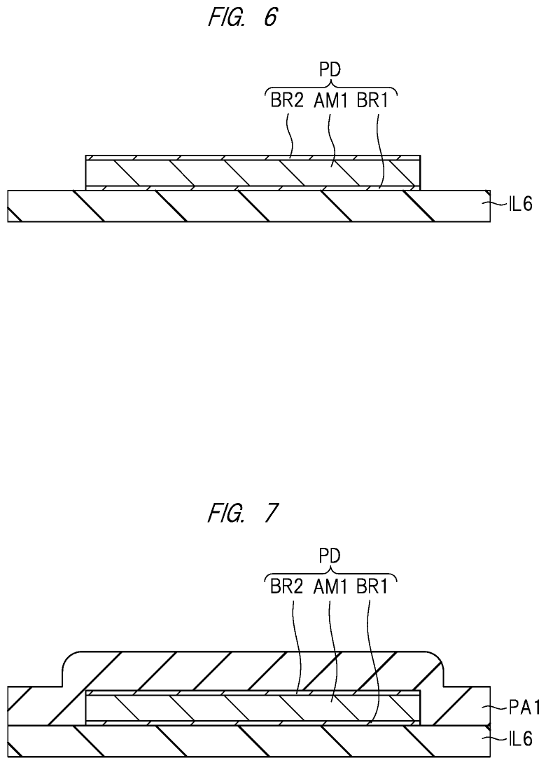

FIG. 5 shows a stacked structure from the semiconductor substrate SB to the fourth wiring layer (the wiring M4 and the interlayer insulation film IL5). However, in subsequent FIGS. 6 to 11, for simplification of the drawings, illustration of the structure below the interlayer insulation film IL6 is omitted. Note that FIG. 5 shows a cross-sectional region corresponding to FIG. 4 while each of FIGS. 6 to 11 shows a cross-sectional region corresponding to FIG. 2. Therefore, in FIGS. 6 to 11, illustration of the opening SH and the via portion V5 is omitted.

Next, as shown in FIG. 6, the pad PD made of the barrier conductor film BR1, the A1-containing conductive film AM1, and the barrier conductor film BR2 is formed on the interlayer insulation film IL6 in which the via portion V5 is embedded. The pad PD can be formed by using a sputtering method or the like of sequentially forming the barrier conductor film BR1, the A1-containing conductive film AM1, and the barrier conductor film BR2 on the interlayer insulation film IL6 in which the via portion V5 is embedded, and then, using a photolithography technique and an etching technique of patterning the stacked film made of the barrier conductor film BR1, the A1-containing conductive film AM1, and the barrier conductor film BR2. At this stage, the entire pad PD is made of the stacked film of the barrier conductor film BR1, the A1-containing conductive film AM1 on the barrier conductor film BR1, and the barrier conductor film BR2 on the A1-containing conductive film AM1.

Next, as shown in FIG. 7, the insulation film PA1 is formed on the interlayer insulation film IL6 so as to cover the pad PD by using a CVD (Chemical Vapor Deposition) method or the like. As described above, the insulation film PA1 is the silicon oxide film.

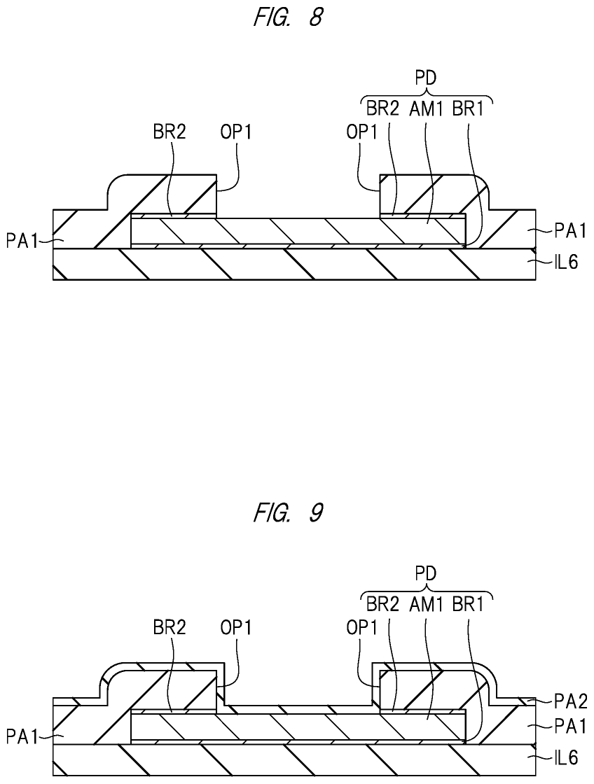

Next, as shown in FIG. 8, the opening OP1 is formed in the insulation film PA1 by using a photolithography technique and an etching technique. The opening OP1 is formed so that the opening OP1 is included in the pad PD in plan view.

In the etching process for forming the opening OP1 in the insulation film PA1, the opening OP1 is formed in the insulation film PA1 by etching the insulation film PA1 to expose the barrier conductor film BR2 of the pad PD from the opening OP1, and then, the barrier conductor film BR2 exposed from the opening OP1 is removed by etching to expose the A1-containing conductive film AM1 of the pad PD from the opening OP1. That is, in the region overlapping the opening OP1 in plan view, not only the insulation film PA1 but also the barrier conductor film BR2 that configures the pad PD are etched and removed, and therefore, the upper surface of the A1-containing conductive film AM1 that configures the pad PD is exposed. In contrast, in the region covered with the insulation film PA1 even after the formation of the opening OP1, the barrier conductor film BR2 is not removed and left.

Next, as shown in FIG. 9, the insulation film PA2 is formed on the insulation film PA1 to cover the pad PD by using a CVD method or the like. As described above, the insulation film PA2 is the silicon nitride film or the silicon oxynitride film. The insulation film PA2 is formed on the insulation film PA1 and on the pad PD exposed from the opening OP1 of the insulation film PA1. At the stage before deposition of the insulation film PA2, the pad PD is exposed from the opening OP1 of the insulation film PA1. However, by the deposition of the insulation film PA2, the pad PD exposed from the opening OP1 of the insulation film PA1 is covered with the insulation film PA2, and therefore, is not exposed.

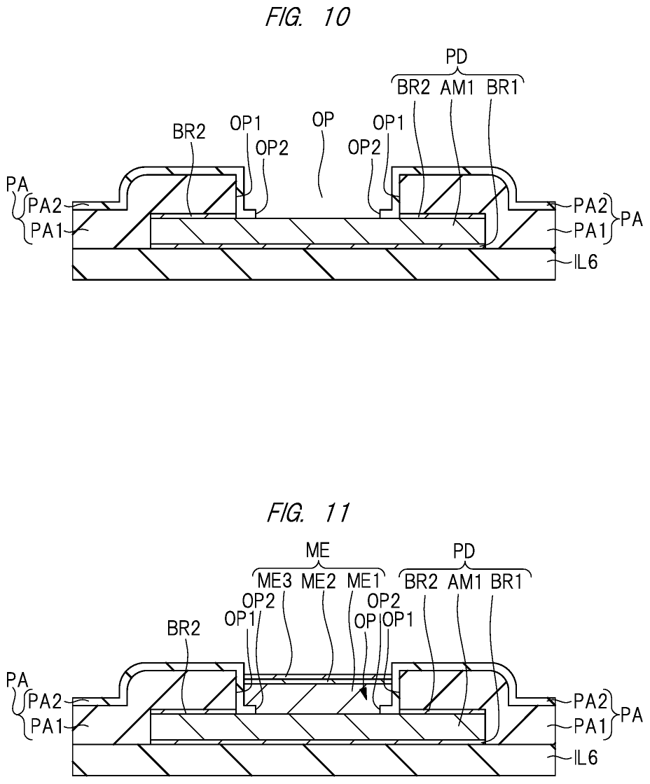

Next, as shown in FIG. 10, the opening OP2 is formed in the insulation film PA2 by using a photolithography technique and an etching technique. The opening OP2 is formed by selectively removing the insulation film PA2 on the pad PD, and is formed so that the opening OP2 is included in the opening OP1 in plan view. The opening OP2 is formed to penetrate through the insulation film PA2, and part of the pad PD is exposed from the opening OP2. At the stage of the deposition of the insulation film PA2, the inner wall of the opening OP1 of the insulation film PA1 is covered with the insulation film PA2. The inner wall of the opening OP1 of the insulation film PA1 remains covered with the insulation film PA2 even after the opening OP2 is formed in the insulation film PA2.

Accordingly, in the plane region where the pad PD is formed, the insulation film PA1 is not exposed because of being covered with the insulation film PA2, and this state is maintained during and after the formation of the opening OP2. That is, the insulation film PA1 is not exposed after the deposition of the insulation film PA2.

Next, as shown in FIG. 11, the metal film (plating film) ME is formed on the pad PD exposed from the opening OP of the insulation film PA (more specifically, the opening OP2 of the insulation film PA2) by using a plating method (preferably, electroless plating method). The metal film ME is preferably made of a stacked film of the nickel plating film ME1, the palladium plating film ME2 thereon, and the gold plating film ME3 thereon. That is, the metal film ME made of the stacked film of the nickel plating film ME1, the palladium plating film ME2 thereon, and the gold plating film ME3 thereon is formed on the pad PD exposed from the opening OP of the insulation film PA by using the plating method (preferably, electroless plating method) of sequentially forming the nickel plating film ME1, the palladium plating film ME2, and the gold plating film ME3. By using the plating method, the metal film ME can be selectively formed on the pad PD exposed from the opening OP of the insulation film PA.

Then, the back surface of the semiconductor substrate SB is ground or polished as necessary to reduce the thickness of the semiconductor substrate SB, and then, the semiconductor substrate SB is diced (cut) together with the stacked structure on the semiconductor substrate SB. At this time, the semiconductor substrate SB and the stacked structure on the semiconductor substrate SB are diced (cut) along a scribe region.

In this manner, the semiconductor device (semiconductor chip) CP can be manufactured.

### Background of Study

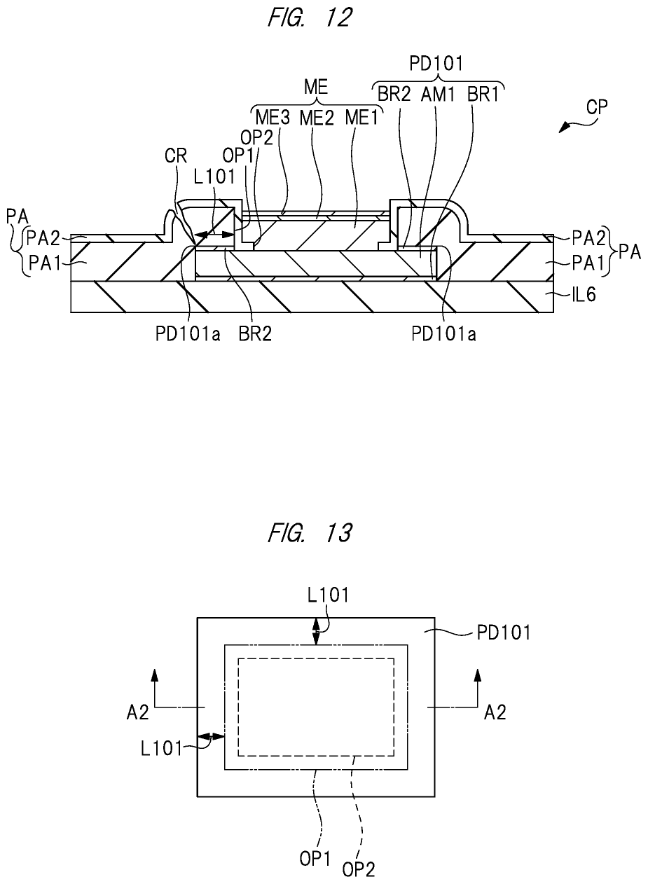

FIG. 12 is a cross-sectional view of a principal part of a semiconductor device according to a study example studied by the present inventors, and corresponds to FIG. 2 described above. Even in FIG. 12, the illustration of the structure below the interlayer insulation film IL6 is omitted. FIG. 13 is a plan view of a pad formation region according to the study example, and corresponds to FIG. 3 described above. A cross-sectional view at a position of a line A2-A2 in FIG. 13 roughly corresponds to FIG. 12.

The study example (FIG. 12 and FIG. 13) differs from the present embodiment (FIG. 2 and FIG. 3) in the following points.

Specifically, a pad PD101 in the study example corresponds to the pad PD in the present embodiment. However, the distance (spacing) L101 from the outer circumference of the pad PD101 to the inner wall of the opening OP1 in the study example is smaller than the distance (spacing) L1 from the outer circumference of the pad PD to the inner wall of the opening OP1 in the present embodiment (L101<L1). In other words, the main feature of the present embodiment is that the distance L1 from the outer circumference of the pad PD to the inner wall of the opening OP1 is made greater than the distance L101 from the outer circumference of the pad PD101 to the inner wall of the opening OP1 in the study example.

Here, the distances L1 and L101 are distances in plan view, and therefore, are the distances in a direction parallel to the main surface of the semiconductor substrate SB. More specifically, the distance L1 is the closest distance between the outer circumference of the pad PD and the inner wall of the opening OP1 in plan view, and the distance L101 is the closest distance between the outer circumference of the pad PD101 and the inner wall of the opening OP1 in plan view. Since the opening OP1 is the opening OP1 of the insulation film PA1, the distance L1 from the outer circumference of the pad PD to the inner wall of the opening OP1 is synonymous with a length (distance) of a portion of the pad PD covered with the insulation film PA1. Also, the distance L101 from the outer circumference of the pad PD101 to the inner wall of the opening OP1 is synonymous with a length (distance) of a portion of the pad PD101 covered with the insulation film PA1.

FIG. 12 also shows a state of occurrence of the crack CR in the insulation film PA near an end portion (corner) PD101a of the pad PD101, although the reason for the occurrence of the crack CR will be described later. As described later, the present embodiment can suppress or prevent the occurrence of such a crack CR.

For other than above, the semiconductor device in the study example has almost the same configuration as that of the semiconductor device according to the present embodiment, and therefore, the repetitive description thereof is omitted.

In the case of the study example, it has been found from the inventor's study that there is a concern of the occurrence of the crack CR in the insulation film PA which is the passivation film due to the stress of the nickel plating film MEL included in the metal film ME which is the OPM film. This will be explained below.

Specifically, in the formation by the plating method (preferably, electroless plating method), the nickel plating film ME1 has an amorphous structure immediately after being formed by the plating method. However, during various heating processes (or under a high temperature environment) after the formation of the metal film ME which is the OPM film, the nickel plating film ME1 having the amorphous structure is crystallized, and therefore, the stress of the nickel plating film MEL is increased because of it. The heating processes that may crystallize the nickel plating film ME1 having the amorphous structure include, for example, a heating process during a wafer testing process, a heating process during an assembly process, heating resulting from an environment under which a manufactured or shipped product is used, or others.

The wafer test process is performed after forming the metal film ME which is the OPM film and before the dicing process (semiconductor substrate cutting process). In the wafer test process, electrical testing of the semiconductor element formed on the semiconductor substrate is performed by, for example, pressing a test probe against the metal film ME formed on the pad. In the wafer test process, in some cases, the electrical test is performed after the semiconductor wafer is heated at a relatively high temperature (for example, 250° C. or higher). The heating process in this case is, for example, a retention baking process, and is performed for a relatively long time (for example, 1 to 10 hours).

The assembly process corresponds to the process of manufacturing the semiconductor package using the semiconductor chip (semiconductor device CP) obtained in the dicing process. In this assembly process, the semiconductor chip is heated at a relatively high temperature (for example, 250° C. or higher) in some cases. The heating process in this case is, for example, a solder reflow process.

When the stress of the nickel plating film MEL is increased by the crystallization of the nickel plating film MEL having the amorphous structure, the stress of the nickel plating film ME1 is transmitted through the hard insulation film PA2, and therefore, a part of the insulation film PA located on the pad PD101 is stretched toward the metal film ME. As a result, cracks become easy to occur in the insulation film PA near the end portion (corner) PD101a of the pad PD101. That is, the crack CR as shown in FIG. 12 becomes easy to occur.

The insulation film PA1 made of silicon oxide is softer (its Young's modulus is lower) than the insulation film PA2 made of silicon nitride or silicon oxynitride. Therefore, if the insulation film PA does not have the insulation film PA2, even in the increase of the stress of the nickel plating film ME1 because of the crystallization of the nickel plating film ME1 having the amorphous structure, the stress of the nickel plating film ME1 is relaxed (absorbed) by the soft insulation film PA1, and therefore, there is hardly concern of the occurrence of the crack CR in the insulation film PA near the end portion PD101a of the pad PD101. However, the insulation film PA1 made of silicon oxide is a film that easily absorbs moisture. Therefore, it is necessary to form the insulation film PA2 made of silicon nitride or silicon oxynitride on the insulation film PA1 to cover the insulation film PA1 with the insulation film PA2. This can suppress or prevent moisture absorption of the insulation film PA1. Therefore, the insulation film PA2 covering the insulation film PA1 is needed. However, the insulation film PA2 made of silicon nitride or silicon oxynitride is harder than the insulation film PA1 made of silicon oxide. Therefore, in the increase of the stress of the nickel plating film ME because of the crystallization of the nickel plating film ME1 having the amorphous structure, the stress of the nickel plating film ME1 is transmitted through the hard insulation film PA2, the part of the insulation film PA located on the pad PD101 is stretched toward the metal film ME, and the crack CR described above becomes easy to occur.

If the inner wall of the opening OP1 of the insulation film PA1 is not covered with the insulation film PA2, the nickel plating film MEL is in contact with the insulation film PA1 that configures the inner wall of the opening OP1. In this case, even in the increase of the stress of the nickel plating film ME1 because of the crystallization of the nickel plating film ME1 having the amorphous structure, the stress of the nickel plating film ME1 is easily relaxed (absorbed) by the soft insulation film PA1, and therefore, the risk of the occurrence of the crack CR in the insulation film PA near the end portion PD101a of the pad PD101 is small. However, if the inner wall of the opening OP1 of the insulation film PA1 is not covered with the insulation film PA2, there is concern that the insulation film PA1 absorbs moisture through the inner wall of the opening OP1 of the insulation film PA1. Also, if the inner wall of the opening OP1 of the insulation film PA1 is not covered with the insulation film PA2, there is concern that the end surface of the barrier conductor film BR2 exposed at the inner wall of the opening OP1 of the insulation film PA1 is oxidized in or before the plating process of forming the metal film ME. Therefore, the inner wall of the opening OP1 of the insulation film PA1 is covered with the insulation film PA2.

The occurrence of the crack CR in the insulation film PA near the end portion PD101a of the pad PD101 leads to the degradation of the reliability of the semiconductor device. For example, moisture can penetrate through the crack CR and cause degradation of the pad PD. Therefore, it is desirable to suppress or prevent the crack from occurring in the insulation film PA due to the increase of the stress of the nickel plating film ME1 because of the crystallization of the nickel plating film ME1 having the amorphous structure.

### Main Features and Effects

The semiconductor device CP according to the present embodiment includes the semiconductor substrate SB, the insulation film IL6 formed on the semiconductor substrate SB, and the pad PD formed on the insulation film IL. The semiconductor device CP according to the present embodiment further includes the insulation film PA1 formed on the insulation film IL6 so as to cover the pad PD and having the opening OP1 partially exposing the pad PD, the insulation film PA2 formed on the insulation film PA1 and having the opening OP2 partially exposing the pad PD, and the metal film ME formed on the pad PD exposed from the opening OP2. The insulation film PA1 is made of silicon oxide, and the insulation film PA2 is made of silicon nitride or silicon oxynitride. In plan view, the opening OP1 is included in the pad PD, and the opening OP2 is included in the opening OP1. The inner wall of the opening OP1 of the insulation film PA1 is covered with the insulation film PA2. The metal film ME includes the nickel plating film ME1 in contact with the pad PD.

One of the main features according to the present embodiment is that the thickness T1 of the nickel plating film ME1 is equal to or greater than 2.5 μm, and that the distance L1 from the outer circumference of the pad PD to the inner wall of the opening OP1 and the thickness T1 of the nickel plating film ME1 satisfy the following formula 1.

L1>T1×2.45−4.61 μm (Formula 1)

A unit of each of L1 and T1 in Formula 1 is “μm”. With this feature, occurrence of a substance corresponding to the crack CR in the insulation film PA can be suppressed or prevented, and therefore, the reliability of the semiconductor device is improved. This will be specifically described below.

The nickel plating film MEL has the function of receiving the impact during wire bonding. In order to prevent the crack from occurring in the metal film ME due to impact during wire bonding, it is effective to increase the thickness T1 of the nickel plating film ME1. In addition, in order to prevent the impact during wire bonding from being transmitted to the pad PD and the structure below the pad PD, it is effective to increase the thickness T1 of the nickel plating film ME1. In this respect, it is desirable to increase the thickness T1 of the nickel plating film ME1.

However, as explained in the chapter “Background of Study”, there is the risk of the occurrence of the crack CR in the insulation film PA due to the stress in the crystallization of the nickel plating film ME1 having the amorphous structure. The greater the thickness T1 of the nickel plating film MEL is, the larger this risk is. This is because the greater the thickness T1 of the nickel plating film ME1 is, the larger the stress generated in the crystallization of the nickel plating film ME1 having the amorphous structure is.

A reason why the stress generated in the crystallization of the nickel plating film ME having the amorphous structure generates the crack in the insulation film PA is that the nickel plating film ME1 is not in contact with the soft insulation film PA1 but with the insulation film PA2 which is harder than the insulation film PA1, the stress is transmitted through the hard insulation film PA2, and the part of the insulation film PA located on the pad PD is stretched toward the metal film ME. The stretching of the part of the insulation film PA located on the pad PD toward the metal film ME becomes a cause of the crack in the insulation film PA near an end portion PDa of the pad PD.

The insulation film PA2 which is made of silicon nitride or silicon oxide is the hard film, and therefore, can hardly provide the function of relaxing the stress generated in the crystallization of the nickel plating film ME1 having the amorphous structure. In contrast, the insulation film PA1 which is made of silicon oxide is the softer film, and therefore, can provide the function of relaxing the stress generated in the crystallization of the nickel plating film ME1 having the amorphous structure. Therefore, the greater the length of the part of the insulation film PA1 located on the pad PD is, the easier the relaxation of the stress generated in the crystallization of the nickel plating film ME1 having the amorphous structure by the insulation film PA1 is. Therefore, even if the part of the insulation film PA located on the pad PD is stretched toward the metal film ME, the crack is difficult to occur in the insulation film PA near the end portion PDa of the pad PD. Here, the length of the part of the insulation film PA1 located on the pad PD is equal to the distance L1 from the outer circumference of the pad PD to the inner wall of the opening OP1. Therefore, the greater the distance L1 from the outer circumference of the pad PD to the inner wall of the opening OP1 is, the easier the relaxation of the stress generated in the crystallization of the nickel plating film ME1 having the amorphous structure by the insulation film PA1 is. Therefore, even if the part of the insulation film PA located on the pad PD is stretched toward the metal film ME, the crack is difficult to occur in the insulation film PA near the end portion PDa of the pad PD.

That is, in comparison between the study example and the present embodiment, the distance (L1, L101) from the outer circumference of the pads (PD, PD101) to the inner wall of the opening OP1 is greater in the present embodiment than the study example, and therefore, the relaxation of the stress generated in the crystallization of the nickel plating film MEL having the amorphous structure is easily relaxed by the insulation film PA1. Therefore, even if the part of the insulation film PA located on the pad (PD, PD101) is stretched toward the metal film ME due to the stress generated in the crystallization of the nickel plating film ME1, the crack is more difficult in the present embodiment to occur in the insulation film PA near the end portion (PDa, PD101a) of the pad (PD, PD101) than the study example.

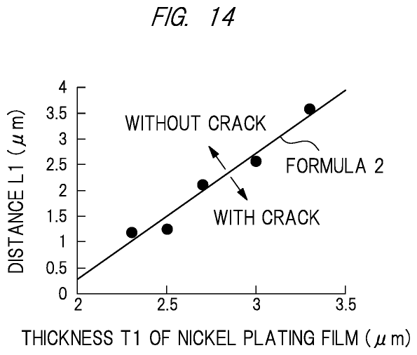

Accordingly, the present inventors have studied how much distance L1 from the outer circumference of the pad PD to the inner wall of the opening OP1 should be secured in order to prevent the crack CR from occurring in the insulation film PA. FIG. 14 is a graph obtained as a result of the inventor's study. FIG. 14 is the graph showing the correlation between the thickness T1 of the nickel plating film MEL and the distance L1 required to prevent the crack CR from occurring in the insulation film PA. A horizontal axis of the graph in FIG. 14 corresponds to the thickness T1 of the nickel plating film ME1. A vertical axis of the graph in FIG. 14 corresponds to the distance L1 from the outer circumference of the pad PD to the inner wall of the opening OP1, and therefore, corresponds to the length of the part of the insulation film PA1 located on the pad PD.

In FIG. 14, for each case where the thickness T1 of the nickel plating film ME1 is 2.3 μm, 2.5 μm, 2.7 μm, 3.0 μm, and 3.3 μm, it was observed whether the crack CR is generated in the insulation film PA while changing the distance L1 from the outer circumference of the pad PD to the inner wall of opening OP1, and the distance L1 without the occurrence of the crack CR in the insulation film PA was obtained and was plotted. A result from the plot is the above-described formula 1. Note that a straight line indicated as Formula 2 in the graph in FIG. 14 has the relation of the following formula 2.

L1=T1×2.45−4.61 μm (Formula 2)

In the graph in FIG. 14, a range below the straight line indicated as Formula 2 has a possibility of the occurrence of the crack CR in the insulation film PA. In a range above the straight line indicated as Formula 2, the occurrence of the crack CR in the insulation film PA can be prevented.

Accordingly, the crack CR can be suppressed or prevented from occurring in the insulation film PA if the distance L1 from the outer circumference of the pad PD to the inner wall of the opening OP1 and the thickness T1 of the nickel plating film ME1 satisfy the above formula 1, in other words, if the distance L1 from the outer circumference of the pad PD to the inner wall of the opening OP1 is greater than a value that is obtained by subtracting 4.61 μm from a value 2.45 times the thickness T1 of the nickel plating film ME1.

For example, when the thickness T1 of the nickel plating film ME1 is 3 μm, the distance L1 from the outer circumference of the pad PD to the inner wall of the opening OP1 needs only to be greater than 2.74 μm, and therefore, the occurrence of the crack CR in the insulation film PA can be suppressed or prevented. When the thickness T1 of the nickel plating film ME1 is 3.5 μm, the distance L1 from the outer circumference of the pad PD to the inner wall of the opening OP1 needs only to be greater than 3.96 μm, and therefore, the occurrence of the crack CR in the insulation film PA can be suppressed or prevented. When the thickness T1 of the nickel plating film MEL is 4 μm, the distance L1 from the outer circumference of the pad PD to the inner wall of the opening OP1 needs only to be greater than 5.19 μm, and therefore, the occurrence of the crack CR in the insulation film PA can be suppressed or prevented.

If the issue of the occurrence of the crack CR as explained in the chapter “Background of Study” was not found, even if the thickness T1 of the nickel plating film MEL is increased, the distance L1 from the outer circumference of the pad PD to the inner wall of the opening OP1 is not increased. This is because a wire bondable region in the pad PD is not increased even in the increase in the distance L1 from the outer circumference of the pad PD to the inner wall of the opening OP1 since the wire bondable region is defined by the opening OP2, and this may cause a risk of increase in the plane dimension (plane area) of the semiconductor device. Only because the present inventors have found the issue as explained in the chapter “Background of Study”, the present inventors increase the distance L1 from the outer circumference of the pad PD to the inner wall of the opening OP1 in the increase in the thickness T1 of the nickel plating film ME1 so that the above formula 1 is satisfied in accordance with the thickness T1 of the nickel plating film ME1. This can suppress or prevent the occurrence of the substance corresponding to the crack CR in the insulation film PA, and therefore, the reliability of the semiconductor device is improved.

Accordingly, it is significant to apply this technical idea of the present embodiment to the case of the increase in the thickness T1 of the nickel plating film ME1. In the present embodiment, the thickness T1 of the nickel plating film ME1 is increased in order to improve the function of the nickel plating film ME1 to receive the impact during wire bonding, and in accordance with that, the distance L1 from the outer circumference of the pad PD to the inner wall of the opening OP1 is increased so that the above formula 1 is satisfied in consideration of the increase in the stress generated in the crystallization of the nickel plating film ME1 having the amorphous structure. Therefore, the occurrence of the crack in the insulation film PA due to the stress generated in the crystallization of the nickel plating film ME1 having the amorphous structure can be prevented.

Thus, in the present embodiment, in order to improve the function of receiving the impact during wire bonding, the thickness T1 of the nickel plating film MEL is set to be equal to or greater than 2.5 μm, or more preferably equal to or larger than 3 μm. Therefore, the occurrence of the crack in the metal film ME due to impact during wire bonding can be suppressed or prevented, and also the impact during wire bonding can be suppressed or prevented from being transmitted to the pad PD and the structure below the pad PD.

### Second Embodiment

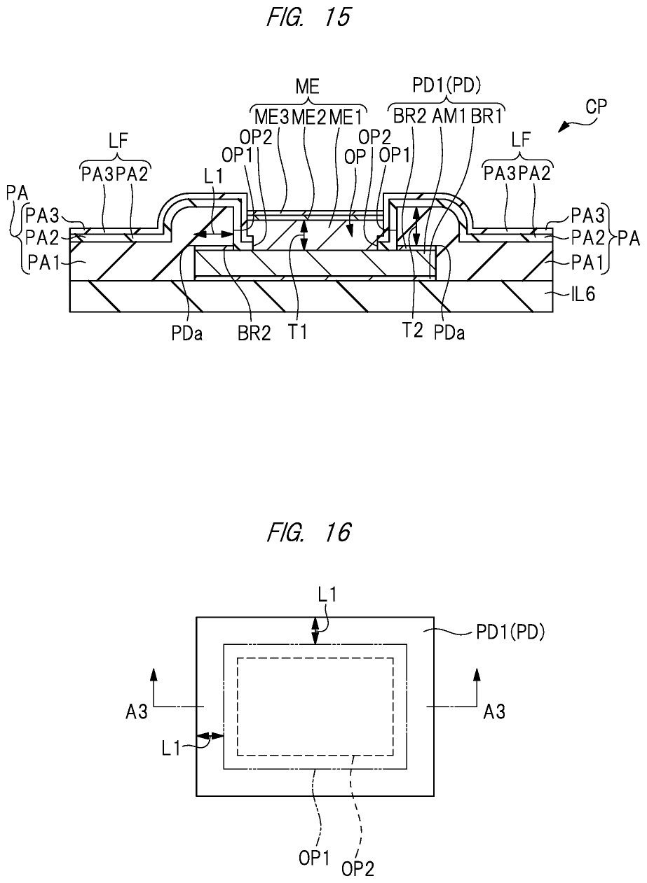

FIG. 15 is a cross-sectional view of a principal part of the semiconductor device CP according to a second embodiment, and corresponds to FIG. 2 described above. Even in FIG. 15, the illustration of the structure below the interlayer insulation film IL6 is omitted. FIG. 16 is a plan view of a pad formation region according to the second embodiment, and roughly corresponds to FIG. 3. A cross-sectional view at a position of a line A3-A3 in FIG. 16 roughly corresponds to FIG. 15. In the following, the pad PD according to the second embodiment is referred to as a pad PD1 with a symbol PD1.

The semiconductor device according to the second embodiment differs from the semiconductor device according to the first embodiment described above in the following points. Specifically, in the present embodiment, the insulation film PA is made of the insulation film PA1 made of silicon oxide, and the insulation film PA2 made of silicon nitride or silicon oxynitride on the insulation film PA1. In contrast, in the second embodiment, the insulation film PA is made of the insulation film PA1 made of silicon oxide, the insulation film PA2 made of silicon nitride or silicon oxynitride on the insulation film PA1, and an insulation film PA3 on the insulation film PA2. The insulation film PA3 is formed on the insulation film PA2, and the insulation film PA3 is in contact with the upper surface of the insulation film PA2.

The insulation film PA3 used in the second embodiment is an inorganic insulation film. And, the Young's modulus of the insulation film PA3 is lower than the Young's modulus of the insulation film PA2. That is, the insulation film PA3 is softer than the insulation film PA2. A silicon oxide film can be preferably used as the insulation film PA3. The thickness of the insulation film PA3 can preferably be about 50 nm to 500 nm.

In the first embodiment described above, the distance L1 from the outer circumference of the pad PD to the inner wall of the opening OP1 of the insulation film PA1 needs to satisfy the above formula 1. However, in the second embodiment, the distance L1 from the outer circumference of the pad PD1 to the inner wall of the opening OP1 of the insulation film PA1 does not need to satisfy the above formula 1. If the thickness of the nickel plating film MEL and the plane dimension (plane area) of the opening OP1 are the same between the second embodiment and the present embodiment, the plane dimension (plane area) of the pad PD1 in the second embodiment can be made smaller than the plane dimension (plane area) of the pad PD in the first embodiment. Therefore, the second embodiment is more advantageous for the downsizing (area reduction) of the semiconductor device than the first embodiment.

Therefore, the second embodiment also allows a case where the following formula 3 is satisfied.

L1≤T1×2.45−4.61 μm (Formula 3)

When the formula 3 is satisfied, the distance L1 from the outer circumference of pad PD1 to the inner wall of the opening OP1 of the insulation film PA1 can be shortened, and therefore, the downsizing (area reduction) of the semiconductor device is achieved.

In the second embodiment, the opening OP2 is formed so as to penetrate through the insulation film PA3 and the insulation film PA2. Hereinafter, a stacked film of the insulation film PA2 and the insulation film PA3 on the insulation film PA2 is referred to as stacked film LF with a symbol LF. The opening OP2 is formed in the stacked film LF of the insulation film PA2 and the insulation film PA3 on the insulation film PA2, and the inner wall of the opening OP2 of the insulation film PA2 is aligned (continuous) with the inner wall of the opening OP2 of the insulation film PA3.

In the second embodiment, the insulation film PA3 is formed on the insulation film PA2, and therefore, an end surface of the insulation film PA2 which configures the inner wall of the opening OP2 is in contact with the nickel plating film ME1. However, except for this end surface, the insulation film PA2 is not in contact with the nickel plating film ME1. Instead, the insulation film PA3 is in contact with the nickel plating film ME1.

In the second embodiment, the inner wall of the opening OP1 of the insulation film PA1 is covered with the insulation film PA2, and the insulation film PA3 is formed on the insulation film PA2. Therefore, the inner wall of the opening OP of the insulation film PA is made of the inner wall of the opening OP2 of the insulation film PA2 (that is, the end surface of the insulation film PA2), the inner wall of the opening OP2 of the insulation film PA3 (that is, the end surface of the insulation film PA3), and the surface of the stacked film LF located on the inner wall of the opening OP1 of the insulation film PA1. Since the top layer of the stacked film LF is the insulation film PA3, the surface of the stacked film LF is made of the surface of the insulation film PA3. The portion of the pad PD1 exposed from the opening OP of the insulation film PA corresponds to the portion of the pad PD1 exposed from the opening OP2 of the insulation film PA2. The position and shape (area) of the opening OP of the insulation film PA is substantially defined by the opening OP2 of the insulation film PA2, and the exposed area of the pad PD1 (the area of the portion of the pad PD1 exposed from the opening OP of the insulation film PA1) is defined by the opening OP2 of the insulation film PA2.

Other configurations of the semiconductor device in the second embodiment are basically the same as in the embodiment described above, and therefore, the repetitive description thereof is omitted here.

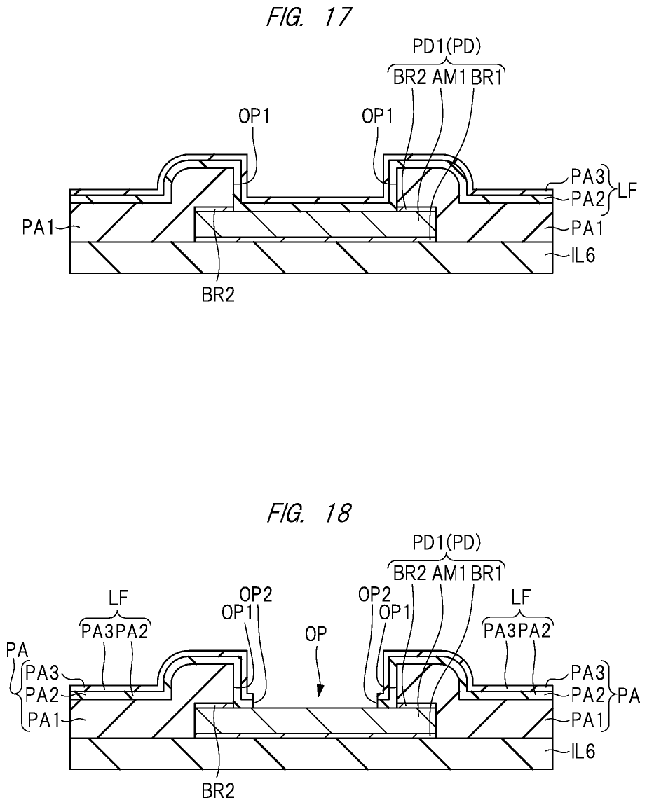

Next, the manufacturing process of the semiconductor device CP according to the second embodiment will be described with reference to FIG. 17 and FIG. 18. Each of FIG. 17 and FIG. 18 is a cross-sectional view of a principal part of the semiconductor device CP according to the present embodiment in the manufacturing process. In FIG. 17 and FIG. 18, the illustration of the structure below the interlayer insulation film IL6 is omitted.

Also in the second embodiment, the same structure as in FIG. 7 described above is provided by performing up to the process of forming the insulation film PA2 as similar to the first embodiment. However, the plane dimension (plane area) of pad PD1 is smaller in the second embodiment than the present embodiment. This is because the distance L1 from the outer circumference of pad PD1 to the inner wall of the opening OP1 of the insulation film PA1 can be made smaller in the second embodiment than the present embodiment as described above.

The process to provide the structure shown in FIG. 7 described above in the second embodiment is basically the same as in the present embodiment, and therefore, the repetitive description thereof is omitted here.

In the second embodiment, after forming the insulation film PA2, the insulation film PA3 is formed on the insulation film PA2 as shown in FIG. 17. The insulation film PA3 is formed over the entire upper surface of the insulation film PA2. If the insulation film PA3 is a silicon oxide film, the silicon oxide film can be formed by using a CVD method or the like.

Next, as shown in FIG. 18, the opening OP2 is formed in the stacked film LF made of the insulation film PA2 and the insulation film PA3 on the insulation film PA2 by using a photolithography technique and an etching technique. Also in the second embodiment, the opening OP2 is formed so as to be included in the opening OP1 in plan view as similar to the first embodiment. The opening OP2 is formed to penetrate through the insulation film PA3 and the insulation film PA2, and part of the pad PD1 is exposed from the opening OP2. At the stage of deposition of the insulation film PA2, the inner wall of the opening OP1 of the insulation film PA1 is covered with the insulation film PA2. Even if the opening OP2 is formed after the insulation film PA3 is formed, the inner wall of the opening OP1 of the insulation film PA1 remains covered with the insulation film PA2.

Therefore, in the plane region where the pad PD1 is formed, the insulation film PA1 is not exposed because of being covered with the insulation film PA2, and this state is maintained during and after the formation of the opening OP2. That is, after the deposition of the insulation film PA2, the insulation film PA1 is not exposed.

Next, as shown in FIG. 15 described above, the metal film ME is formed on the pad PD1 exposed from the opening OP of the insulation film PA (more specifically, the opening OP2 of the insulation films PA2 and PA3) by using a plating method (preferably, electroless plating method). That is, the nickel plating film ME1, the palladium plating film ME2, and the gold plating film ME3 are sequentially formed on the pad PD1 exposed from the opening OP of the insulation film PA by using the plating method (preferably, electroless plating method), and therefore, the metal film ME made of the stacked film of the nickel plating film ME1, the palladium plating film ME2 formed on it, and the gold plating film ME3 formed on it. By using the plating method, the metal film ME can be selectively formed on the pad PD1 exposed from the opening OP of the insulation film PA.

Then, the back surface of the semiconductor substrate SB is ground or polished as necessary to reduce the thickness of the semiconductor substrate SB, and then, the semiconductor substrate SB is diced (cut) together with the stacked structure on the semiconductor substrate SB. In this process, the semiconductor substrate SB and the stacked structure on the semiconductor substrate SB are diced (cut) along a scribing region.

In this manner, the semiconductor device (semiconductor chip) CP according to the second embodiment can be manufactured.

One of the main features of the second embodiment is that the insulation film PA3 which is the inorganic insulation film is formed on the insulation film PA2 made of silicon nitride or silicon oxynitride, and the Young's modulus of the insulation film PA3 is lower than the Young's modulus of the insulation film PA2. The opening OP2 is formed so as to penetrate through the insulation films PA3 and PA2.

Since the Young's modulus of the insulation film PA3 is lower than the Young's modulus of the insulation film PA2, the insulation film PA3 is softer than the insulation film PA2, and is a film that easily relaxes (absorbs) the stress generated in the crystallization of the nickel plating film ME1 having the amorphous structure. In the second embodiment, since the insulation film PA3 is formed on the insulation film PA2, the end surface of the insulation film PA2 which configures the inner wall of the opening OP2 is in contact with the nickel plating film ME1. However, except for this end surface, the insulation film PA2 is not in contact with the nickel plating film ME1, and the nickel plating film ME1 is mainly in contact with the surface of the pad PD1 (in this case, the surface of the A1-containing conductive film AM1) and the insulation film PA3. Since the nickel plating film MEL is hardly in contact with the insulation film PA2 which has a high Young's modulus (and is therefore hard) but is in contact with the insulation film PA3 which has a low Young's modulus (and is therefore soft), the stress generated in the crystallization of the nickel plating film ME1 having the amorphous structure can be relieved (absorbed) by the insulation film PA3. Therefore, the part of the insulation film PA located on the pad is less likely to be stretched toward the metal film ME against the stress generated in the crystallization of the nickel plating film ME1 in the second embodiment with the formation of the insulation film PA3 on the insulation film PA2 than the study example without the formation of the insulation film PA3, and therefore, the crack is more difficult to occur in the insulation film PA near the end portion (PDa, PD101a) of the pad (PD, PD101).

Also, since the insulation film PA1 is a silicon oxide film, the Young's modulus of the insulation film PA1 is lower than the Young's modulus of the insulation film PA2 made of silicon nitride or silicon oxynitride. Therefore, in the second embodiment, the insulation film PA which is a passivation film has a structure in which the insulation film PA2 which has a high Young's modulus is sandwiched between the insulation films PA1 and PA3 which have a lower Young's modulus than that of the insulation film PA2. By this structure, the stress generated in the crystallization of the nickel plating film MEL can be relaxed (absorbed) by the insulation film PA1 and insulation film PA3. As a result, the part of the insulation film PA located on the pad PD1 is less likely to be stretched toward the metal film ME against the stress generated in the crystallization of the nickel plating film ME1, and therefore, the crack is more difficult to occur in the insulation film PA near the end portion PDa of the pad PD101.

Thus, the second embodiment adopts the structure in which the nickel plating film MEL is hardly in contact with the hard insulation film PA2 but is mainly in contact with the soft insulation film PA3, e structure in which and the hard insulation film PA2 is sandwiched between the soft insulation films PA1 and PA3. This can suppress or prevent the occurrence of the crack in the insulation film PA due to the stress generated in the crystallization of the nickel plating film ME1. Thus, the reliability of the semiconductor device can be improved.

In addition, in the second embodiment, the distance L1 from the outer circumference of pad PD1 to the inner wall of the opening OP1 of the insulation film PA1 does not need to satisfy the above formula 1 since the insulation film PA3 is formed on the insulation film PA2 to prevent the occurrence of the crack CR in the insulation film PA. Therefore, the second embodiment is more advantageous for the downsizing (area reduction) of the semiconductor device than the first embodiment.

Meanwhile, in the first embodiment, the number of manufacturing processes does not need to be increased since the distance L1 from the outer circumference of the pad PD to the inner wall of the opening OP1 of the insulation film PA1 only needs to be increased in accordance with the thickness T1 of the nickel plating film ME1. Therefore, the number of manufacturing processes can be more suppressed in the first embodiment than the second embodiment.

In addition, in the second embodiment, a silicon oxide film can be preferably used as the insulation film PA3. However, when the insulation film PA3 is a silicon oxide film, there is a possibility that the insulation film PA3 absorbs moisture. Even if the insulation film PA3 absorbs moisture, the moisture is suppressed or prevented from moving from the insulation film PA3 to the insulation film PA1 since the insulation film PA2 made of silicon nitride or silicon oxynitride is interposed between the insulation film PA3 and the insulation film PA1. Therefore, even if the silicon oxide film is used as the insulation film PA3, the problem of the moisture absorption in the insulation film PA1 does not arise.

The insulation film PA3 is not an organic insulation film such as a resin film but the inorganic insulation film. The organic insulation film such as the resin film has low adhesion to the nickel plating film, while the inorganic insulation film has high adhesion to the nickel plating film. Therefore, when not the organic insulation film such as the resin film but the inorganic insulation film is used as the insulation film PA3, the adhesion between the nickel plating film MEL and the insulation film PA3 can be enhanced. As a result, occurrence of peeling of the nickel plating film MEL can be suppressed or prevented. Therefore, the reliability of the semiconductor device can be improved more accurately.

### Third Embodiment

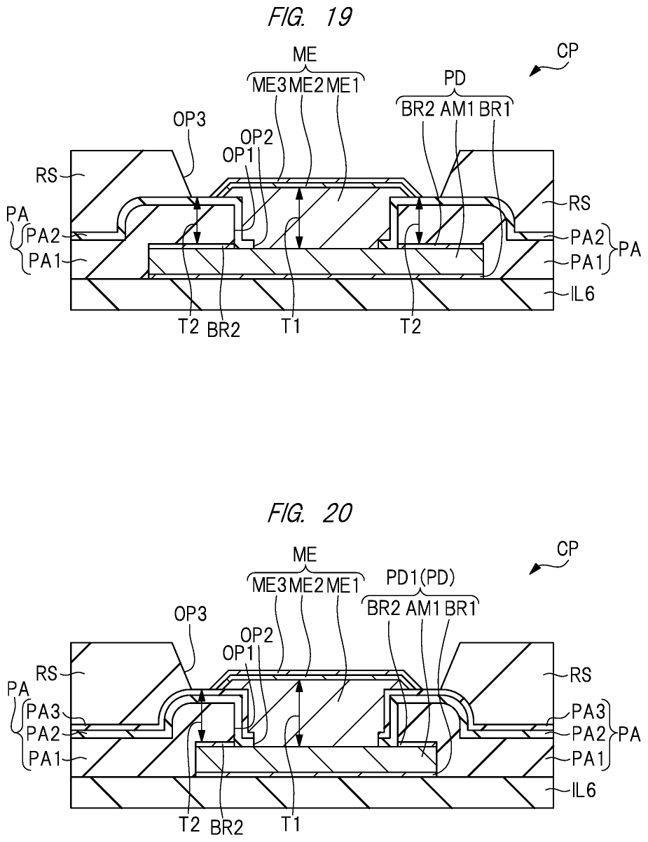

The third embodiment corresponds to a modification example of the first embodiment described above. FIG. 19 is a cross-sectional view of a principal part of the semiconductor device CP according to the third embodiment, and corresponds to FIG. 2 described above. Even in FIG. 19, the illustration of the structure below the interlayer insulation film IL6 is omitted. Since the plan view showing the pad formation region in the third embodiment is the same as FIG. 3 described above, the repetitive description thereof is omitted here. Different points of the third embodiment from the first embodiment described above will be described below. The repetitive description of the same points of the third embodiment with the first embodiment described above is omitted here.

In the case of the first embodiment described above, the thickness T1 of the nickel plating film ME1 is equal to or smaller than the thickness T2 of the insulation film PA (T1≤T2). In the cases of the first embodiment described above and the third embodiment, the insulation film PA is made of the insulation film PA1 and the insulation film PA2, and therefore, the thickness of the insulation film PA is the sum of the thicknesses of the insulation film PAL and the insulation film PA2. Therefore, in the first embodiment described above, the nickel plating film ME1 is not formed outside the opening OP of the insulation film PA, and therefore, the nickel plating film ME1 is not formed on the insulation film PA (insulation film PA2) outside the opening OP.

In contrast, in the third embodiment, the thickness T1 of the nickel plating film MEL is greater than the thickness T2 of the insulation film PA (T1>T2). Therefore, in the third embodiment, the nickel plating film ME1 is also formed outside the opening OP of the insulation film PA, and thus part (outer circumferential part) of the nickel plating film ME1 is formed on the insulation film PA (more specifically, on the insulation film PA2) outside the opening OP.

In the third embodiment, the thickness T1 of the nickel plating film ME1 is greater than in the first embodiment described above, and therefore, the function of the nickel plating film ME1 to receive the impact during wire bonding can be improved. As a result, in the third embodiment, the occurrence of the crack in the metal film ME due to impact during wire bonding can be more accurately suppressed or prevented. And, the transmission of impact during wire bonding to the pad PD and the structure below the pad PD can be also more accurately suppressed or prevented.

Also, FIG. 19 shows a case in which the resin film RS is formed on the insulation film PA. The resin film RS has an opening OP3 including the opening OP2 in plan view. Although the resin film RS is not an essential component, the formation of the resin film RS provides the advantage that is easiness of handling of the semiconductor device (semiconductor chip) CP. As the resin film RS, a polyimide resin film or the like can be suitably used.

When the resin film RS is formed on the insulation film PA, it is preferred that the nickel plating film MEL is not in contact with the resin film RS. In the third embodiment, the plane dimension (plane area) of the opening OP3 of the resin film RS is set so that the nickel plating film MEL is not in contact with the resin film RS even if part (outer circumferential part) of the nickel plating film MEL is formed on the insulation film PA (insulation film PA2) outside the opening OP.

The following problems are of concern if the nickel plating film ME1 is in contact with the resin film RS in the formation of the nickel plating film ME1, that is, if part of the nickel plating film ME1 is formed on the resin film RS. That is, the resin film has lower adhesiveness to the nickel plating film than that of the inorganic insulation film such as silicon oxide film and silicon nitride film. Therefore, if part of the nickel plating film ME1 is formed on the resin film RS, the adhesion between the nickel plating film MEL and the resin film RS is reduced at a portion where the nickel plating film MEL is in contact with the resin film RS, and there is a concern of peeling of the nickel plating film ME1 from this portion. In addition, there is concern that the plating solution enters a gap between the nickel plating film MEL and the resin film RS when the palladium plating film ME2 or the gold plating film ME3 is formed after the nickel plating film ME1 is formed.

In contrast, in the third embodiment, the nickel plating film MEL is not in contact with the resin film RS. That is, the nickel plating film MEL is not formed on the resin film RS. Since the nickel plating film ME1 is in contact with the insulation film PA2 but not with the resin film RS, the adhesion of the nickel plating film ME1 to a base member film (in this case, the insulation film PA2) can be improved, and the peeling of the nickel plating film ME1 can be accurately prevented. Also, it is possible to accurately prevent the entering of the plating solution to the gap between the nickel plating film MEL and the base member film (in this case, the insulation film PA2) when the palladium plating film ME2 or the gold plating film ME3 is formed after the nickel plating film MEL is formed.

### Fourth Embodiment

The fourth embodiment corresponds to a modification example of the second embodiment described above. FIG. 20 is a cross-sectional view of a principal part of the semiconductor device CP according to the fourth embodiment, and corresponds to FIG. 15 described above. Even in FIG. 20, the illustration of the structure below the interlayer insulation film IL6 is omitted. Since the plan view showing the pad formation region in the fourth embodiment is the same as FIG. 16 described above, the repetitive description thereof is omitted here. Different points of the fourth embodiment from the second embodiment described above will be described below. The repetitive description of the same points of the fourth embodiment with the second embodiment described above is omitted here.

In the case of the second embodiment described above, the thickness T1 of the nickel plating film MEL is equal to or smaller than the thickness T2 of the insulation film PA (T1≤T2). In the cases of the second embodiment described above and the fourth embodiment, the insulation film PA is made of the insulation films PA1, PA2 and PA3. Therefore, the thickness of the insulation film PA is the sum of the thicknesses of the insulation film PA1, insulation film PA2 and insulation film PA3. Therefore, in the second embodiment described above, the nickel plating film ME1 is not formed outside the opening OP of the insulation film PA, and therefore, the nickel plating film MEL is not formed on the insulation film PA (insulation film PA2) outside the opening OP.

In contrast, in the fourth embodiment, the thickness T1 of the nickel plating film MEL is larger than the thickness T2 of the insulation film PA (T1>T2). Therefore, in the fourth embodiment, the nickel plating film MEL is also formed outside the opening OP of the insulation film PA, and thus part (outer circumferential part) of the nickel plating film MEL is formed on the insulation film PA (more specifically, on the insulation film PA3) outside the opening OP.

In the fourth embodiment, the thickness T1 of the nickel plating film MEL is larger than in the second embodiment described above, and therefore, the function of the nickel plating film ME1 to receive the impact during wire bonding can be improved. Its effect is as described in the third embodiment. Also, FIG. 20 shows a case in which the resin film RS is formed on the insulation film PA. The resin film RS has the opening OP3 including the opening OP2 in plan view. Although the resin film RS is not an essential component, the formation of the resin film RS is as described in the third embodiment.

When the resin film RS is formed on the insulation film PA, it is preferred even in the fourth embodiment that the nickel plating film ME1 is not in contact with the resin film RS as similar to the third embodiment. Therefore, the plane dimension (plane area) of the opening OP3 of the resin film RS is set so that the nickel plating film MEL is not in contact with the resin film RS even if part (outer circumferential part) of the nickel plating film MEL is formed on the insulation film PA (insulation film PA2) outside the opening OP.

As similar to the third embodiment described above, even in the fourth embodiment, the nickel plating film MEL is not in contact with the resin film RS, and therefore, the nickel plating film ME1 is not formed on the resin film RS. As a result, the adhesion of the nickel plating film ME1 to the base member film (in this case, the insulation film PA2) can be improved, and the peeling of the nickel plating film MEL can be accurately prevented. Also, it is possible to accurately prevent the entering of the plating solution to the gap between the nickel plating film ME1 and the base member film (in this case, the insulation film PA2) when the palladium plating film ME2 or the gold plating film ME3 is formed after the nickel plating film ME1 is formed.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A semiconductor device comprising:
a semiconductor substrate;
a first insulation film formed on the semiconductor substrate;
a pad formed on the first insulation film;
a second insulation film formed on the first insulation film so as to cover the pad, the second insulation film including a first opening partially exposing the pad;
a third insulation film formed on the second insulation film, the third insulation film including a second opening partially exposing the pad; and
a metal film formed on the pad exposed from the second opening,
wherein the second insulation film is made of silicon oxide,
wherein the third insulation film is made of silicon nitride or silicon oxynitride,
wherein the first opening is included in the pad in plan view,
wherein the second opening is included in the first opening in plan view,
wherein an inner wall of the first opening of the second insulation film is covered with the third insulation film,
wherein the metal film includes a nickel plating film in contact with the pad, and
wherein, when a distance from an outer circumference of the pad to the inner wall of the first opening is L1 (μm) while a thickness of the nickel plating film is T1 (μm), T1 is equal to or greater than 2.5 μm, and the following Formula 1 is satisfied.
L1>T1×2.45−4.61 μm Formula 1

2. The semiconductor device according to claim 1,
wherein the thickness T1 of the nickel plating film is equal to or greater than 3 μm.

3. The semiconductor device according to claim 1,
wherein the nickel plating film is a nickel electroless plating film.

4. The semiconductor device according to claim 1,
wherein the metal film includes a gold plating film formed on the nickel plating film.

5. The semiconductor device according to claim 1,
wherein the metal film includes:
a palladium plating film formed on the nickel plating film; and
a gold plating film formed on the palladium plating film.

6. The semiconductor device according to claim 1,
wherein the pad includes an A1-containing conductive film mainly made of aluminum.

7. The semiconductor device according to claim 1,
wherein the thickness of the nickel plating film is equal to or smaller than a sum of a thickness of the second insulation film and a thickness of the third insulation film.

8. The semiconductor device according to claim 1,
wherein the thickness of the nickel plating film is greater than a sum of a thickness of the second insulation film and a thickness of the third insulation film.

9. The semiconductor device according to claim 8, comprising:
a resin film formed on the third insulation film,
wherein the resin film includes a third opening including the second opening in plan view, and
wherein the nickel plating film is formed so as not to be in contact with the resin film.

10. A semiconductor device comprising:
a semiconductor substrate;
a first insulation film formed on the semiconductor substrate;
a pad formed on the first insulation film;
a second insulation film formed on the first insulation film so as to cover the pad, the second insulation film including a first opening partially exposing the pad;
a third insulation film formed on the second insulation film, the third insulation film including a second opening partially exposing the pad;
a fourth insulation film formed on the third insulation film; and
a metal film formed on the pad exposed from the second opening,
wherein the second insulation film is made of silicon oxide,
wherein the third insulation film is made of silicon nitride or silicon oxynitride,
wherein the first opening is included in the pad in plan view,
wherein the second opening is included in the first opening in plan view,
wherein an inner wall of the first opening of the second insulation film is covered with the third insulation film,
wherein the metal film includes a nickel plating film in contact with the pad,
wherein the fourth insulation film is an inorganic insulation film, and
wherein a Young's modulus of the fourth insulation film is lower than a Young's modulus of the third insulation film.

11. The semiconductor device according to claim 10,
wherein the second opening is formed so as to penetrate through the fourth insulation film and the third insulation film.

12. The semiconductor device according to claim 10,
wherein the fourth insulation film is made of silicon oxide.

13. The semiconductor device according to claim 10,
wherein the nickel plating film is a nickel electroless plating film.

14. The semiconductor device according to claim 10,
wherein the metal film includes a gold plating film formed on the nickel plating film.

15. The semiconductor device according to claim 10,
wherein the metal film includes:
a palladium plating film formed on the nickel plating film; and
a gold plating film formed on the palladium plating film.

16. The semiconductor device according to claim 10,
wherein the pad includes an A1-containing conductive film mainly made of aluminum.

17. The semiconductor device according to claim 10,
wherein a thickness of the nickel plating film is equal to or smaller than a sum of a thickness of the second insulation film and a thickness of the third insulation film.

18. The semiconductor device according to claim 10,
wherein a thickness of the nickel plating film is greater than a sum of a thickness of the second insulation film and a thickness of the third insulation film.

19. The semiconductor device according to claim 18, comprising:
a resin film formed on the third insulation film,
wherein the resin film includes a third opening including the second opening in plan view, and
wherein the nickel plating film is formed so as not to be in contact with the resin film.

20. The semiconductor device according to claim 18,
wherein the thickness of the nickel plating film is equal to or greater than 2.5 μm.
